(19) United States
(12) Patent Application Publication
(10) Pub. No.: US 2014/0054765 A1
(43) Pub. Date: Feb. 27, 2014

(54) DRIVING CHIP AND METHOD OF MANUFACTURING THE SAME

(71) Applicant: SAMSUNG DISPLAY CO., LTD., Yongin-City (KR)

(72) Inventors: Seo-Hyeong YANG, Yongin-City (KR); Gil-Jae Lee, Yongin-City (KR); Jeong-Kyoo Kim, Yongin-City (KR)

(73) Assignee: Samsung Display Co., Ltd., Yongin-City (KR)

(21) Appl. No.: 13/752,122

(22) Filed: Jan. 28, 2013

(30) Foreign Application Priority Data
Aug. 22, 2012 (KR) 10-2012-0091997

(51) Int. Cl. H01L 23/498; H01L 23/00

(52) U.S. Cl. CPC H01L 23/49811
USPC 257/737; 438/121

(57) ABSTRACT

A driving chip and a method of manufacturing the driving chip are disclosed. In one aspect, the method includes forming an inside metal portion of a connection terminal on a base element by patterning a first metal layer; forming a first insulating layer on the inside metal portion of the connection terminal; forming an inside metal portion of a dummy terminal on the first insulating layer by patterning a second metal layer; and forming a bump portion on the inside metal portion of the connection terminal and on a second metal portion of the dummy terminal. The driving chip may suppress warp transformation or pressure mark of the driving chip and thus, the reliability of the driving chip may be improved.

### CROSS-REFERENCE TO RELATED APPLICATIONS

This application claims the benefit of Korean Patent Application No. 10-2012-0091997, filed on Aug. 22, 2012, in the Korean Intellectual Property Office, the disclosure of which is incorporated herein in its entirety by reference.

### BACKGROUND

1. Field

The present disclosure relates to a driving chip, which is mounted on a panel of a display device, such as a flat panel display device or the like, and a method of manufacturing the driving chip. This disclosure also relates to an improved driving chip, which may improve the reliability of coupling to a panel, and a method of manufacturing the driving chip.

2. Description of the Related Technology

Many components are involved in displaying images on a display apparatus. These components are disposed in a panel of a flat panel display device such as an organic light-emitting diode (OLED) display device, a liquid crystal display device, or the like, and are connected to a driving chip that is mounted on the panel.

The driving chip, among other functions, converts image data supplied from the external signal into a driving signal suitable to drive the panel of the flat panel display device and of applying the driving signal to the components.

Recently, a chip on glass (COG) mounting method has been used as a method of mounting a driving chip on a panel. The COG mounting method mounts a driving chip directly on a panel, and is a method of electrically connecting a driving chip to a panel by pressing, at high temperature, the driving chip with an anisotropic conductive film disposed between the driving chip and the panel.

The COG mounting method has the advantage of being simple, but has a disadvantage that the driving chip is warped because it is performed at high temperature. Furthermore, as panels become thinner, a pressure mark may also occur on the driving chip due to warping of the panel. For example, since in a driving chip, the region including terminals that directly contact the panel is supported by the strength of the terminals, a warp transformation does not occur in that region. However, since the region between the terminals does not have a force counteract or resist the external force of COG mounting, the region between the terminals may be easily warped and a pressure mark may also occur on the space between the terminals due to a warp of the panel. In general, since the terminals are formed along an edge portion of the driving chip, the central portion of the driving chip is empty. This empty space of the central portion of the driving chip is frequently warped and a pressure mark frequently occurs in that empty space.

Accordingly, a method of manufacturing a driving chip which effectively prevents a warp transformation, is required.

### SUMMARY OF CERTAIN INVENTIVE ASPECTS

The present disclosure provides an improved driving chip which suppresses a warp transformation occurring either in the driving chip or the panel, and further prevents a pressure mark due to a warp of a panel.

In some embodiments, there is provided a method of manufacturing a driving chip, the method including: forming an inside metal portion of at least one connection terminal on a base element by patterning a first metal layer; forming a first insulating layer on the inside metal portion of the at least one connection terminal; forming an inside metal portion of at least one dummy terminal on the first insulating layer by patterning a second metal layer; and forming a bump portion on the inside metal portion of the connection terminal and on the inside metal portion of the at least one dummy terminal.

When patterning the first metal layer, the inside metal portion of at least one dummy terminal is formed.

The method may further include forming a second insulating layer on the inside metal portion of the dummy terminal.

After exposing the inside metal portion of the connection terminal and the inside metal portion of the dummy terminal by pattering the first and second insulating layers, the bump portion may be attached on the exposed portion of the at least one connection terminal and the inside metal portion of the at least one dummy terminal.

The connection terminal may include a plurality of connection terminals and the plurality of connection terminals may be formed along an edge of the base element, and the dummy terminal may include a plurality of dummy terminals and the plurality of dummy terminals may be formed in a line along a long side of the base element in the center portion of the base element.

The first metal layer and the second metal layer each may include an aluminum material.

The bump portion may include a gold material.

In some embodiments, there is provided a driving chip including: a plurality of connection terminals disposed on a base element configured to interchange electrical signals with a connection object; and a dummy terminal disposed between the plurality of connection terminals and electrically isolated, wherein the connection terminals and dummy terminal each comprise an inside metal portion disposed in the base element and a bump portion that is formed on the inside metal portion and protrudes to the outside to contact the connection object.

The inside metal portion of each of the plurality of connection terminals may be formed in a first insulating layer disposed on the base element, and the inside metal portion of the dummy terminal may be formed in a second insulating layer that is formed on the first insulating layer.

The inside metal portion of a connection terminal may be formed also under the inside metal portion of the dummy terminal.

The plurality of connection terminals may be formed along an edge of the base element, and the dummy terminal may include a plurality of dummy terminals and the plurality of dummy terminals may be formed in a plurality of lines along a long side of the base element in the center portion of the base element.

The inside metal portion of each of the plurality of connection terminals and the inside metal portion of the dummy terminal each may include an aluminum material.

The bump portion may include a gold material.

According to the driving chip according to the present invention and in some embodiments, in the method of manufacturing the driving chip, a warp transformation of the driving chip may be suppressed and a phenomenon, in which a pressure mark occurs on the driving chip due to a warp of a panel, may be prevented, and thus, the reliability of the driving chip may be improved.

### BRIEF DESCRIPTION OF THE DRAWINGS

The above and other features and advantages of the present disclosure will become more apparent by describing in detail exemplary embodiments thereof with reference to the attached drawings in which:

FIG. 1 is a perspective view schematically illustrating an unmounted driving chip configured to couple to a panel of a flat panel display device.

FIG. 2 is a cross-sectional view taken along line II-II of FIG. 1.

FIGS. 3A through 3L are diagrams sequentially illustrating a method of manufacturing a driving chip illustrated in FIG. 2.

FIG. 4 is a diagram illustrating an embodiment of a driving chip.

### DETAILED DESCRIPTION

Certain embodiments of a driving chip and a method of manufacturing a driving chip will now be described more fully with reference to the accompanying drawings. It will be understood that when an element such as a layer, film, region, or substrate is referred to as being “on” or “over” another element, it can be directly on the other element or intervening elements may also be present. Similarly, when an element is referred to as being “under” another element, it can be directly under the other element, or intervening elements may also be present.

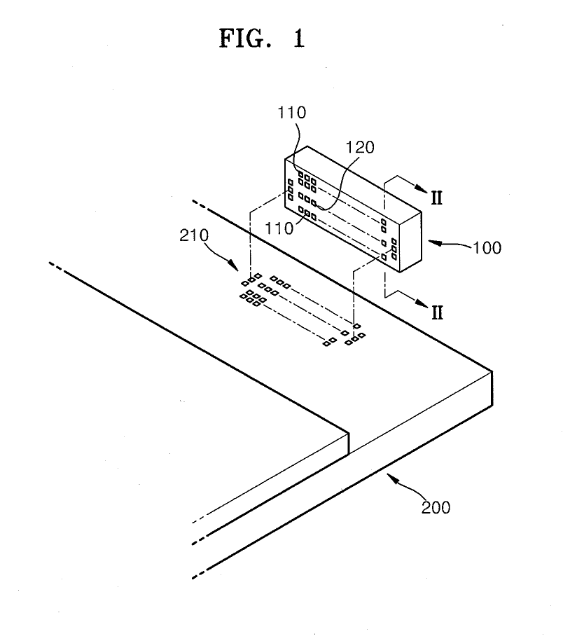

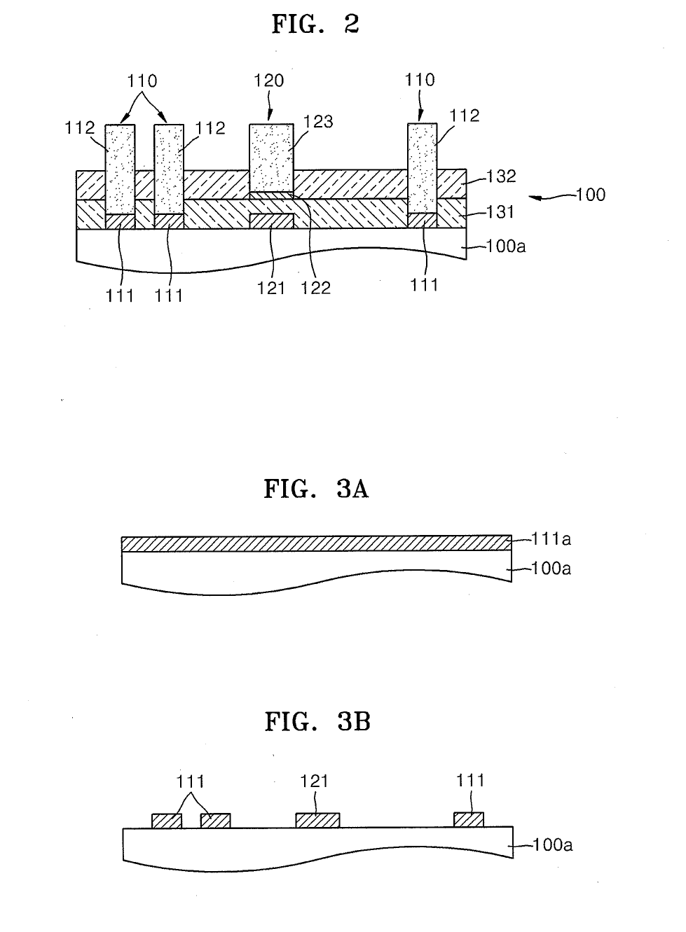

FIG. 1 is a diagram illustrating, illustrating an unmounted driving chip 100 configured to couple to a pad portion 210 of a panel 200 of a flat panel display device, and FIG. 2 is a cross-sectional view taken along line II-II of FIG. 1.

As illustrated in FIG. 1, the panel 200 includes the pad portion 210 that is connected to internal components (not shown), and the driving chip 100 is connected to the pad portion 210 and, thus, is electrically connected to the internal components.

Connection terminals 110 that are configured to be coupled to the pad portion 210, are disposed along the edge or perimeter of the driving chip 100. In the area of the driving chip 100 between the connection terminals 110, or, in the central portion of the driving chip 100, electrically isolated dummy terminals 120 are formed in a line which runs in a direction corresponding to the long side of the driving chip 100. The dummy terminals 120 support the central portion of the driving chip 100, thereby preventing warping of the driving chip 100. The dummy terminals 120 also support the connection terminals 110, which provide electrical connection with the components. Accordingly, the dummy terminals 120 do not provide an electrical connection, and prevent warping of the driving chip 100. Because the dummy terminals 120 are disposed between the connection terminals 110 in a central portion of the driving chip 100, the dummy terminals 120thus provide support and counteract the external force applied during chip mounting. Therefore warp transformations are unlikely to occur when pressing the driving chip 100 to mount it on the pad portion 210 of the panel 200, and a pressure mark on the driving chip 100 due to a warp of the panel 200 also is unlikely to occur. FIG. 2 depicts a cross-sectional structure of the driving chip 100 that includes the connection terminals 110 and the dummy terminals 120.

As illustrated in FIG. 2, the connection terminals 110 and the dummy terminals 120 are formed on a base element 100a. Each of the connection terminals 110 includes an inside metal portion 111 formed of an aluminum material, and a bump portion 112 formed of a gold material, which is connected to the inside metal portion 111 and thus is connected to the pad portion 210. Similarly, each of the dummy terminals 120 includes an inside metal portion 121 formed of an aluminum material. Also, each of the dummy terminals 120 includes a bump portion 112 formed of a gold material. However, unlike the connection terminals 110, the dummy terminals 120are connected to a second metal portion 122. The connection terminals 110 are connected to a circuit portion (not shown) which is disposed in the base element 100a, through the inside metal portion 111. However, the dummy terminals 120 are not electrically connected to the circuit portion because the second metal portion 122 is not connected to any surrounding element and is isolated from surrounding elements. That is, an insulating gap exists between second metal portion 122 and inside metal portion 121. The inside metal portion 121 is formed in the same layer as the inside metal portion 111 of the connection terminals 110. The inside metal portion 121 is formed under the second metal portion 122 of the dummy terminals 120. However, unlike the connection terminals 110, the inside metal portion 121 is separated from the second metal portion 122 of the dummy terminals 120 by a first insulating layer 131. Thus, the dummy terminals 120 are electrically isolated from surrounding elements.

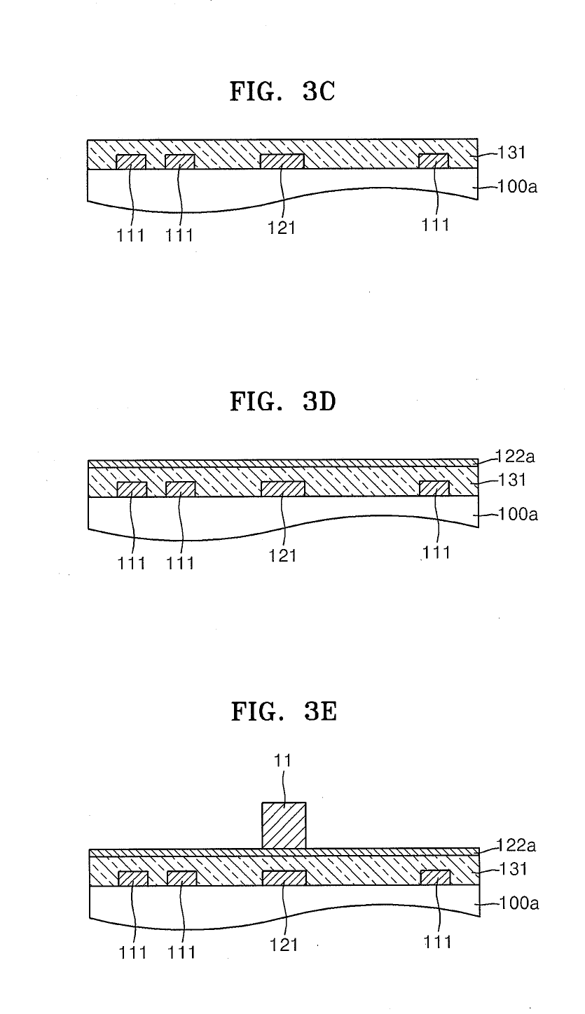

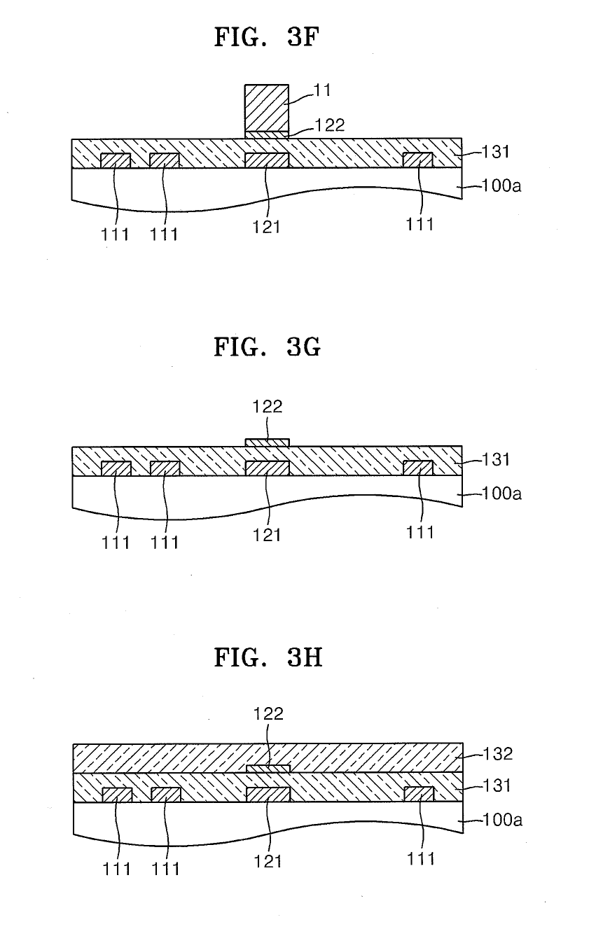

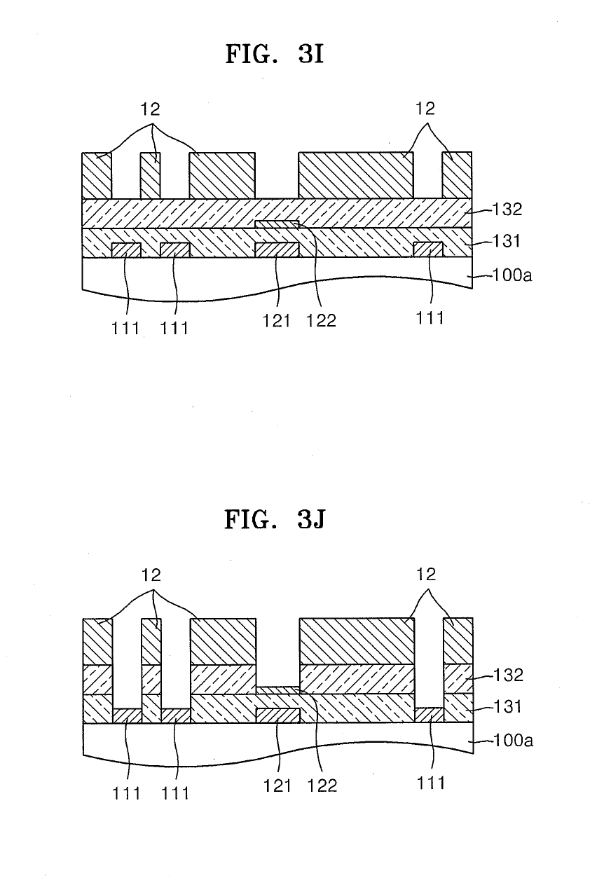

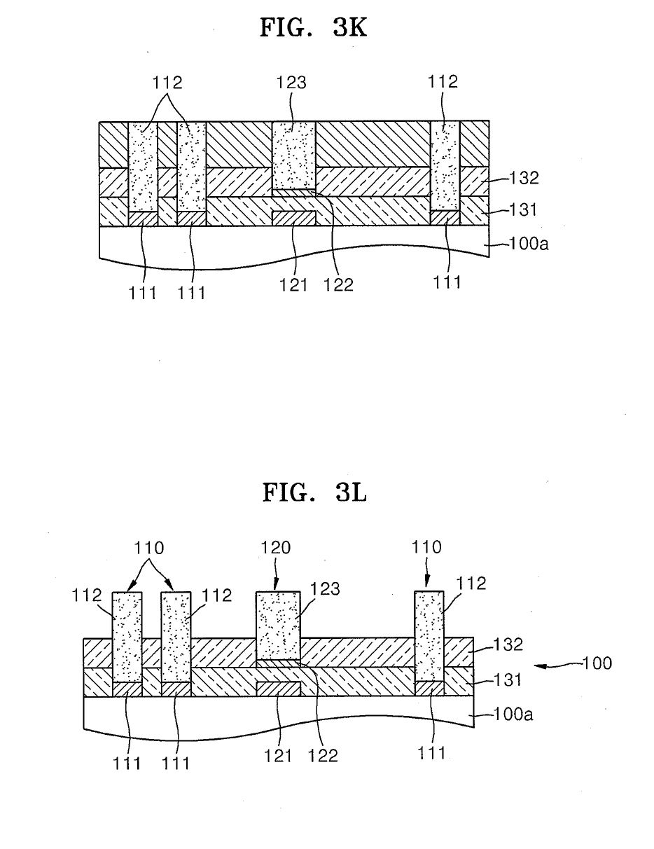

FIGS. 3A through 3L illustrate a method for manufacturing the driving chip 100.

First, a first metal layer 111a is formed on the base element 100a as illustrated in FIG. 3A, and the inside metal portions 111 of the connection terminals 110 are formed, as illustrated in FIG. 3B, by patterning the first metal layer 111a with a first mask (hereinafter, referred to as a base mask). Here, as described above, the inside metal portion 121 may be formed in also an area in which the dummy terminal 120 is to be located. However, the inside metal portion 121 does not perform an electrical connecting function since it is not connected to the dummy terminal 120 to be subsequently formed.

Next, the first insulating layer 131 is formed on the inside metal portions 111 and 121 as illustrated in FIG. 3C, and a second metal layer 122a is formed on the first insulating layer 131 as illustrated in FIG. 3D.

Next, as illustrated in FIG. 3E, a first photoresist layer 11 is formed on the second metal layer 122a. The first photoresist layer 11 is formed on a portion of the second metal layer 122a corresponding to the location where the second metal portion 122 of the dummy terminal 120 is to be formed. The first photoresist layer 11 is patterned by using a second mask (hereinafter referred to as a bump mask). Next, an etching is performed, and at least a portion of second metal layer 122a is removed, and the remaining portion of the second metal layer 122a becomes second metal portion 122 of the dummy terminal 120 is formed, as depicted in FIG. 3F. Following this etching, the first photoresist pattern 11 is removed as depicted in FIG. 3G.

Subsequently, a second insulating layer 132 is formed on the second metal portion 122 of the dummy terminal 120 and the first insulating layer 131 as shown in FIG. 3H. Next, as illustrated in FIG. 31, a second photoresist layer 12 is formed on the second insulating layer 132. The second photoresist layer 12 is patterned to be a third mask (hereinafter referred to as a pad mask) which corresponds to the areas in which the bump portions 112 and 123 are to be formed are patterned by using a third mask . The portions in which the bump portions 112 and 123 are to be formed are the portions corresponding to and over the inside metal portions 111 of the connection terminals 110 and a portion over the second metal portion 122 of the dummy terminals 120.

When an etching is performed in this state, as illustrated in FIG. 3J, the unmasked portions of the second insulation layer 132 and the first insulation layer 12 are removed, and the inside metal portions 111 of the connection terminals 110 and the inside metal portion 122 of the dummy terminals 120 are exposed.

Next, as in FIG. 3K, the bump portions 112 and 123 formed of a gold material are attached on the exposed inside metal portions 111 and second metal portion 122.

The second photoresist layer 12 is then removed, and the driving chip 100, and the method is complete, as illustrated in FIG. 3L.

Therefore, the dummy terminals 120 in driving chip 100 do not form or provide an electrical connection function are disposed between the connection terminals 110. Thus, the dummy terminals 120provide support for driving chip 100 when driving chip 100 is subjected to mounting forces. The dummy terminals 120 counter act the external mounting force, a warp transformation is unlikely to occur when pressing the driving chip 100 to attach it on the pad portion 210 of the panel 200, and a pressure mark due to a warp of the panel 200 also hardly occurs on the driving chip 100.

In addition, since the bump portions 112 and 123 formed of a gold material are attached on the inside metal portions 111 and 122 formed of an aluminum material, a strong bond between the gold and aluminum metals is obtained, and thus, a stable coupling between the pad portion 210 and the driving chip 100 may be secured.

Furthermore, since the driving chip 100 having the above structure is formed by using only three masks, including the base mask, the bump mask, and the pad mask, there is no burden or increased difficulty due to the increase of the number of mask.

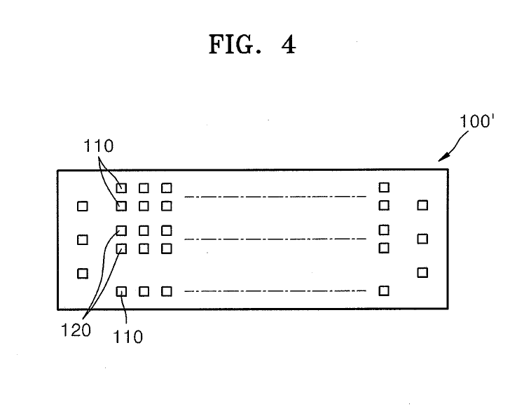

In some embodiments, the dummy terminals 120 are disposed in a line running in the direction corresponding to the long side of the driving chip 100 in the central portion thereof is illustrated as an example. However, as illustrated in FIG. 4, a modified driving chip 100′ dummy terminals 120 may be arranged in a plurality of lines.

TAs dummy terminals 120 is are formed in two or more lines in an empty space between the connection terminals 110, the ability of driving chip 100′ to resist warp transformations and to hold out against external mounting forces. Additionally, by increasing the number of dummy terminals 120, or by forming the dummy terminals 120 in a plurality of lines, the resistance of the panel 20 to warp transformations may be increased. In other words, the dummy terminals 120 may be formed in a plurality of lines within an available space, and a driving chip including the dummy terminals 120 formed in a plurality of lines may be formed in the same manner through the processes of FIGS. 3A through 3L.

The driving chip as described herein and the method of manufacturing the driving chip, as described above, may suppress a warp transformation of the driving chip by using a bearing power of the dummy terminals. Furthermore, the phenomenon in which a pressure mark occurs on the driving chip due to a warp of the panel, may be prevented, and thus, the reliability of the driving chip may be improved.

While the inventive concept has been particularly shown and described with reference to exemplary embodiments thereof, they are provided for the purposes of illustration and it will be understood by those of ordinary skill in the art that various modifications and equivalent other embodiments can be made from the inventive concept. Accordingly, the true technical scope of the inventive concept is defined by the technical spirit of the appended claims.

What is claimed is:

1. A method of manufacturing a driving chip, the method comprising:
forming an inside metal portion of at least one connection terminal on a base element by patterning a first metal layer;
forming a first insulating layer on the inside metal portion of the at least one connection terminal;
forming a metal portion of at least one dummy terminal on the first insulating layer by patterning a second metal layer; and
forming a bump portion on the inside metal portion of the at least one connection terminal and on the inside metal portion of the at least one dummy terminal.

2. The method of claim 1, wherein when patterning the first metal layer, an inside metal portion of the at least one dummy terminal is formed.

3. The method of claim 1, further comprising forming a second insulating layer on the metal portion of the at least one dummy terminal.

4. The method of claim 3, the method comprises exposing the inside metal portion of the at least one connection terminal and the inside metal portion of the at least one dummy terminal by pattering the first and second insulating layers and attaching the bump portion on the exposed inside metal portion of the at least one connection terminal and the inside metal portion of the at least one dummy terminal.

5. The method of claim 1, wherein the at least one connection terminal comprises a plurality of connection terminals and the at least one dummy terminal comprises a plurality of dummy terminals, and wherein the plurality of connection terminals are formed along an edge of the base element, and the plurality of dummy terminals are formed in a center portion of the base element.

6. The method of claim 1, wherein the first metal layer and the second metal layer each comprise an aluminum material.

7. The method of claim 1, wherein the bump portion comprises a gold material.

8. A driving chip comprising:
a plurality of connection terminals disposed on a base element configured to provide an electrical connection with one or more connection objects; and
at least one dummy terminal disposed between the plurality of connection terminals, the dummy terminal being electrically isolated; and
wherein the plurality of connection terminals and the at least one dummy terminal each comprise an inside metal portion disposed on the base element, and a bump portion formed on the inside metal portion and protrudes to the outside to contact the connection object.

9. The driving chip of claim 8, wherein the inside metal portion of each of the plurality of connection terminals is formed in a first insulating layer disposed on the base element, and a second metal portion of the dummy terminal is formed in a second insulating layer that is formed on the first insulating layer.

10. The driving chip of claim 9, wherein an inside metal portion of the at least one dummy terminal is formed under the second metal portion of the at least one dummy terminal.

11. The driving chip of claim 8, wherein the plurality of connection terminals are formed along an edge of the base element, and the at least one dummy terminal comprises a plurality of dummy terminals, and wherein the plurality of dummy terminals are formed in a center portion of the base element.

12. The driving chip of claim 8, wherein the inside metal portion of each of the plurality of connection terminals and the inside metal portion and the second metal portion of the dummy terminal each comprise an aluminum material.

13. The driving chip of claim 8, wherein the bump portion comprises a gold material.
